(19) United States
(12) Patent Application Publication
(10) Pub. No.: US 2015/0221839 A1
(43) Pub. Date: Aug. 6, 2015

(54) LIGHT EMITTING DEVICE PACKAGE AND LIGHTING APPARATUS INCLUDING THE SAME

(71) Applicant: LG INNOTEK CO., LTD., Seoul (KR)

(72) Inventors: Gwui Youn PARK, Seoul (KR); Bo Ra KANG, Seoul (KR); Sung Phil KIM, Seoul (KR)

(21) Appl. No.: 14/614,121

(22) Filed: Feb. 4, 2015

(30) Foreign Application Priority Data
Feb. 5, 2014 (KR) 10-2014-0013148

(51) Int. Cl. H01L 33/58; H01L 25/075

(52) U.S. Cl. CPC H01L 33/58; H01L 25/0753

(57) ABSTRACT

Disclosed are a light emitting device package and a light apparatus including the same. The light emitting device package according to an embodiment of the present disclosure includes a light emitting device that has a first side extending in a first direction and a second side extending in a second direction, and is disposed on a substrate, and a molding unit that has a shape of an isotropic lens disposed on the substrate to surround the light emitting device, wherein a square root of {(length of the first side)²+(length of the second side)²} is smaller than a diameter of the isotropic lens, and the length of the first side is at least 5/3 times more than the length of the second side. According to the present disclosure, the light emitting device may be formed into a rectangular shape or a plurality of light emitting devices may be arranged in a rectangular shape, and therefore an anisotropic illumination distribution may be obtained while applying an isotropic lens which can be easily designed and manufactured, thereby reducing manufacturing time and costs while increasing optical efficiency.

### CROSS-REFERENCE TO RELATED APPLICATION

This application claims priority under 35 U.S.C. §119 to Korean Patent Application No. 10-2014-0013148, filed on Feb. 5, 2014, which entire disclosure is hereby incorporated by reference.

### BACKGROUND

1. Field

The present invention relates to a light emitting device package and a lighting apparatus including the same.

2. Background

A light emitting device such as a light emitting diode (LED) is a type of a semiconductor device that converts electric energy into optical energy through a P-N junction structure of a compound semiconductor, has a small power consumption and long life, and is capable of miniaturization and weight reduction, and thereby has been spotlighted as the next generation light source of a lighting apparatus. In recent years, a blue LED and an ultraviolet (UV) LED that use nitrides having excellent physical and chemical characteristics have been introduced. Since the blue LED or UV LED may implement white light or other monochromatic lights using a phosphor material, application fields of the LED are expanding.

A linear lighting device may be configured using such a light emitting device, and in this instance, in order to reduce the number of required light emitting devices, light emitted from the light emitting device should be more widely diffused in a specific direction. In this manner, in order to obtain an anisotropic light distribution, an anisotropic lens may be mounted, but there are difficulties in anisotropically designing and manufacturing the lens, and optical efficiency is degraded when such a lens is adopted.

### BRIEF DESCRIPTION OF THE DRAWINGS

The embodiments will be described in detail with reference to the following drawings in which like reference numerals refer to like elements wherein:

FIG. 1 is a perspective view showing a light emitting device package according to a first comparative example;

FIG. 2 is a view showing an illumination distribution of the device shown in FIG. 1;

FIG. 3 is a perspective view showing a light emitting device package according to a second comparative example;

FIG. 4 is a view showing an illumination distribution of the device shown in FIG. 3;

FIG. 5 is a perspective view showing a light emitting device package according to a first embodiment of the present disclosure;

FIG. 6 is a view showing an illumination distribution of the device shown in FIG. 5;

FIG. 7 is a plan view showing a light emitting device package according to a second embodiment of the present disclosure;

FIGS. 8 and 9 are views showing an illumination distribution of a linear lighting apparatus configured of a light emitting device package according to a comparative example; and

FIG. 10 is a view showing an illumination distribution of a linear lighting apparatus configured of a light emitting device package according to an embodiment of the present disclosure.

### DETAILED DESCRIPTION

Example embodiments of the present disclosure are disclosed herein. Also, specific structural and functional details disclosed herein are merely representative for purposes of describing the example embodiments of the present disclosure. However, the example embodiments of the present disclosure may be embodied in many alternate forms and should not be construed as limited to example embodiments of the present disclosure set forth herein.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Accordingly, while the disclosure is susceptible to various modifications and alternative forms, specific embodiments thereof are shown by way of example in the drawings and will herein be described in detail. It should be understood, however, that there is no intent to limit the disclosure to the particular forms disclosed, but on the contrary, the disclosure is to cover all modifications, equivalents, and alternatives falling within the spirit and scope of the disclosure. Like numbers refer to like elements throughout the description of the figures.

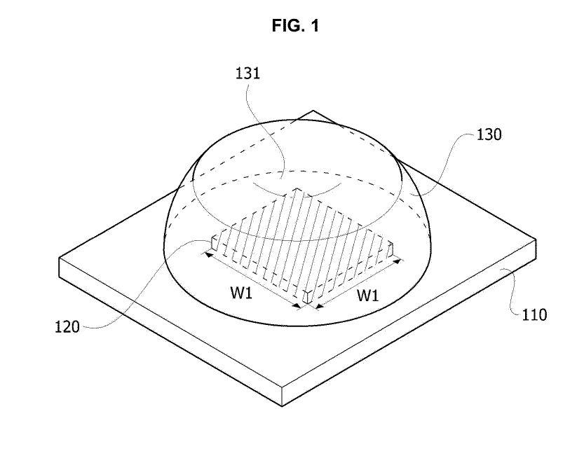

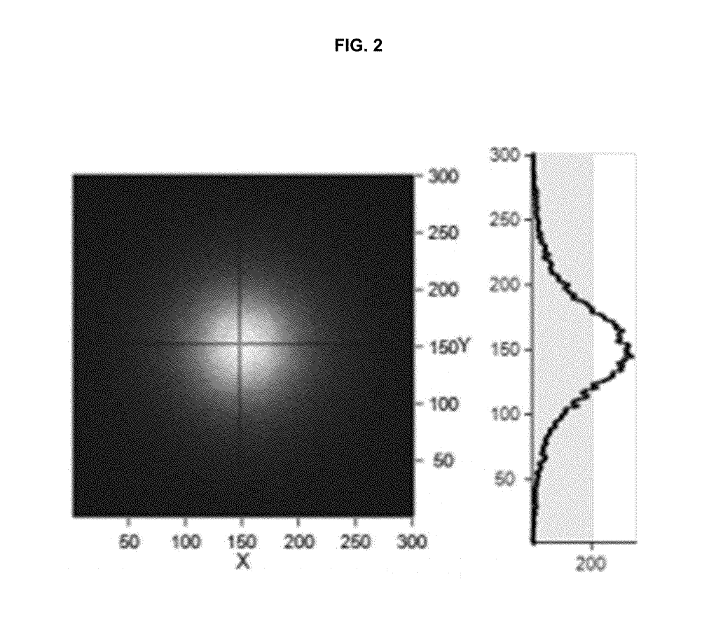

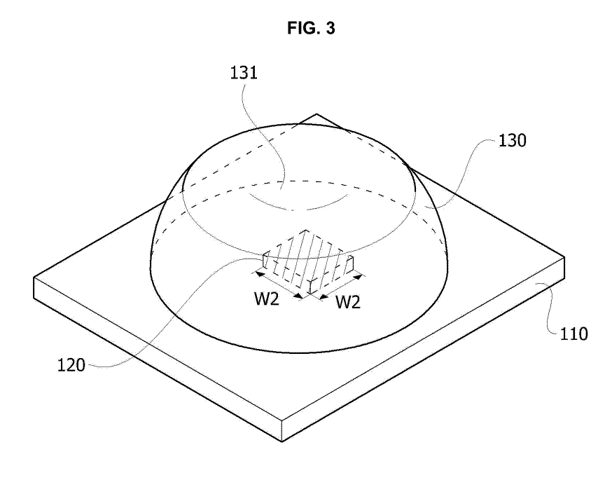

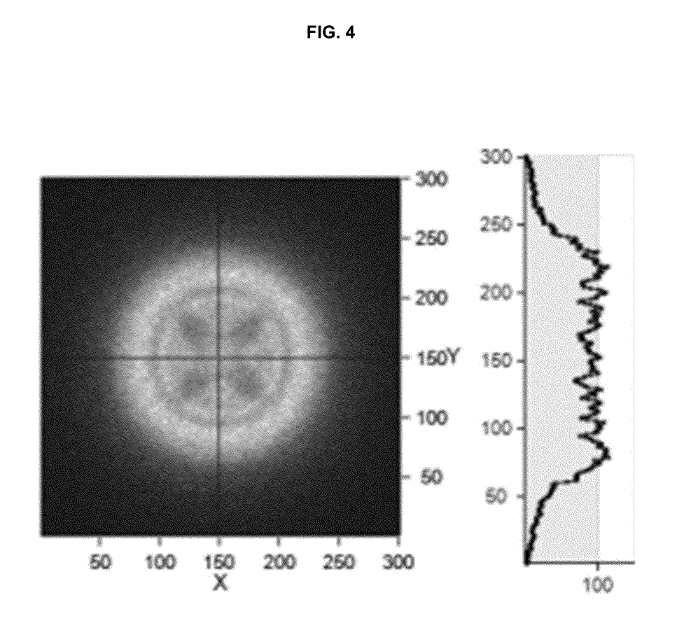

FIG. 1 is a perspective view showing a light emitting device package according to a first comparative example, FIG. 2 is a view showing an illumination distribution of the device shown in FIG. 1, FIG. 3 is a perspective view showing a light emitting device package according to a second comparative example, and FIG. 4 is a view showing an illumination distribution of the device shown in FIG. 3. Here, the unit of the numerical values shown in FIGS. 2 and 4 is mm, and X and Y respectively indicate a first direction and a second direction intersecting the first direction.

Referring to FIGS. 1 and 3, the light emitting device package according to the first and second comparative examples may include a light emitting device 120 that is disposed on a substrate 110, and a molding unit 130 that has a shape of an isotropic lens disposed on the substrate 110 to surround the light emitting device 120. The molding unit 130 may have an aspherical surface shape with a concave portion 131 recessed at the center thereof, and a planar shape of the light emitting device 120 according to the first and second comparative examples may be a square shape. As shown in the drawings, the light emitting device 120 according to the first comparative example may have a first width W1 and the light emitting device 120 according to the second comparative example may have a second width W2 relatively smaller than the first width W1.

Referring to FIGS. 2 and 4, when the molding units 130 according to the first and second comparative examples have the same shape and size, an illumination distribution may be changed depending on the size of the light emitting device 120. Specifically, it can be seen that light emitted from the light emitting device 120 having the second width W2 relatively smaller than the first width W1 is more widely diffused. However, when the planar shape of the light emitting device 120 is the square shape regardless of the size of the light emitting device 120, the light emitted from the light emitting device 120 is isotropically diffused, such as with a circular shape.

Meanwhile, in a linear lighting apparatus or the like, light is required to be more widely diffused in a specific direction, and in order to obtain such an illumination distribution, an anisotropic secondary lens may be mounted. However, it is not easy to design the anisotropic secondary lens, and manufacturing time and costs may be increased while optical efficiency is degraded when the anisotropic secondary lens is applied to a product.

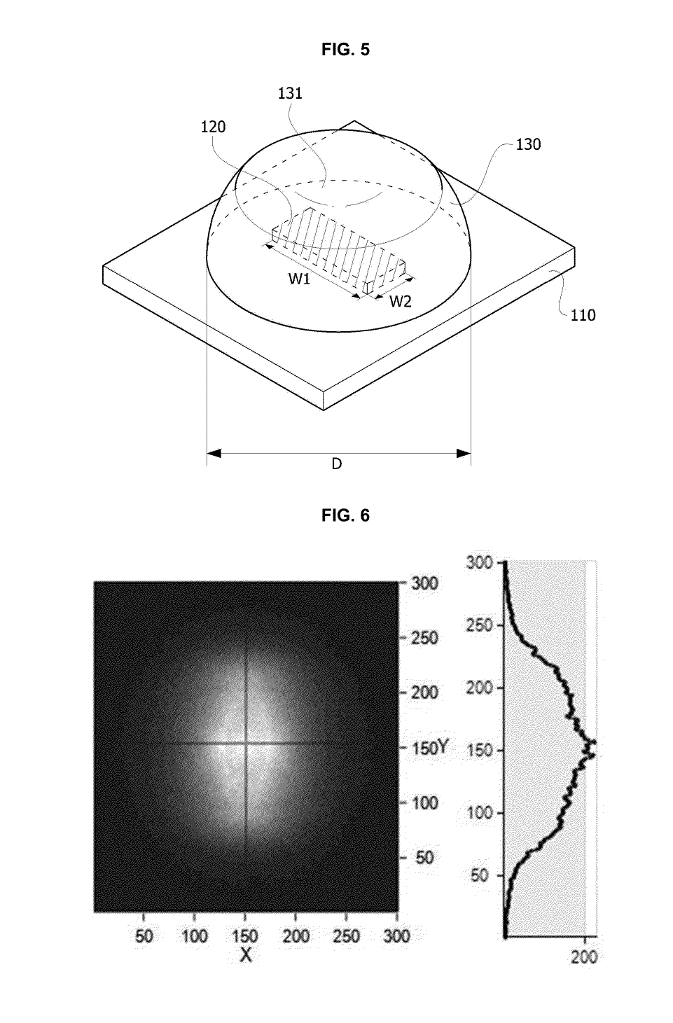

FIG. 5 is a perspective view showing a light emitting device package according to a first embodiment of the present disclosure, and FIG. 6 is a view showing an illumination distribution of the device shown in FIG. 5. Here, the unit of the numerical values shown in FIG. 6 is mm, and X and Y respectively indicate a first direction and a second direction intersecting the first direction.

Referring to FIG. 5, the light emitting device package according to the first embodiment of the present disclosure may include a light emitting device 120 that is disposed on a substrate 110, and a molding unit that has a shape of an isotropic lens disposed on the substrate 110 to surround the light emitting device 120. A planar shape of the light emitting device 120 is a rectangular shape having a long axis W1 and a short axis W2, and a diagonal length of the light emitting device 120 should be smaller than a diameter D of the molding unit 130 so that the molding unit 130 can surround the light emitting device 120 (see, Equation 1).

\sqrt{(W1)²+(W2)²}<D [Equation 1]

The substrate 110 may be a typical printed circuit board (PCB) or a lead frame, and formed of at least one material of alumina, quartz, zirconia, forsterite, cordierite, beryllia, mullite, calcium zirconate, silicon carbide, aluminum nitride, fused silica, low temperature co-fired ceramic (LTCC), plastic, graphite, and a metal.

The light emitting device 120 may be a device that emits light by recombination of minority carriers (electrons or electron holes) injected using a P-N junction structure of a compound semiconductor, and may be a light emitting diode (LED). Although not shown in the present drawing, the light emitting device 120 may be electrically connected to an electrode of the substrate 110 through a wire or the like so that power may be applied to the light emitting device 120, and when the light emitted from the light emitting device 120 is blue light, the light emitting device 120 may include a yellow-based phosphor that converts the blue light into white light. In particular, in order to obtain an anisotropic illumination distribution required for a configuration of the linear lighting apparatus, the long axis W1 of the light emitting device 120 should be longer than the short axis W2 thereof by at least 5/3 times or more, and the anisotropy of the illumination distribution may be increased by increasing a ratio (W1/W2) of the long axis and the short axis of the light emitting device 120.

The molding unit 130 is a lens-integrated type package having the function of a lens while protecting the light emitting device 120, and may have an aspherical surface shape with the concave portion 131 recessed at the center thereof, and therefore it is possible to increase a directional angle of the light emitted from the light emitting device 120. Meanwhile, since the light emitted from the light emitting device 120 should be transmitted to the outside, the molding unit 130 may be formed of transparent resin such as silicon resin or epoxy resin, and a dispersant or a phosphor may be added inside the molding unit 130 according to need.

Referring to FIG. 6, the light emitting device package according to the first embodiment of the present disclosure may obtain the anisotropic illumination distribution by applying the molding unit 130 having the shape of the isotropic lens which can be easily designed and manufactured. Specifically, the light emitted from the light emitting device 120 is more widely diffused in a direction of the short axis W2 rather than in the direction of the long axis W1, and thereby an oval-shaped light distribution appears. Meanwhile, in order to control the light distribution in the direction of the long axis W1 when the molding unit 130 is designed, the light distribution of the square-shaped light emitting device 120 having the first width W1 as shown in the first comparative example may be utilized. Similarly, in order to control the light distribution in the direction of the short axis W2, the light distribution of the square-shaped light emitting device 120 having the second width W2 as shown in the second comparative example may be utilized.

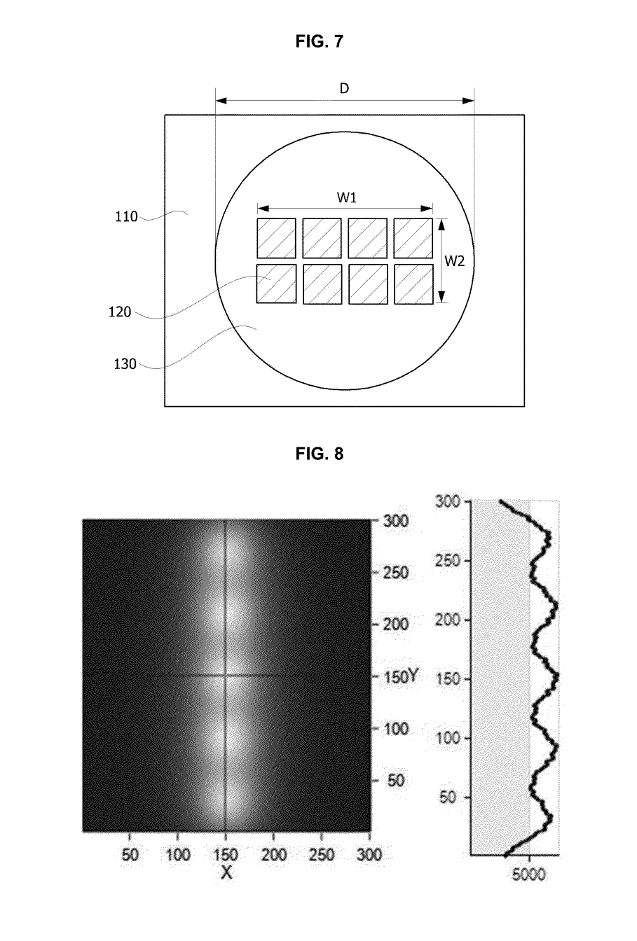

FIG. 7 is a plan view showing a light emitting device package according to a second embodiment of the present disclosure. In the description of the present embodiment, detailed description of substantially the same part as that of the above-described first embodiment will be omitted.

Referring to FIG. 7, the light emitting device package according to the second embodiment of the present disclosure may include a plurality of light emitting devices 120 that are arranged on the substrate 110 so as to have a rectangular shape having the long axis W1 and the short axis W2, and the isotropic lens-shaped molding unit 130 that is disposed on the substrate 110 to surround the plurality of light emitting devices 120. A planar shape of each of the light emitting devices 120 may be a square shape or a rectangular shape, and a diagonal length of the rectangular shape formed by arranging the plurality of light emitting devices 120 should be smaller than the diameter D of the molding unit 130 so that the molding unit 130 can surround the whole of the plurality of light emitting devices 120 (see, Equation 1).

The substrate 110 may be a typical PCB or a lead frame, and formed of a material such as that of the first embodiment. In addition, the light emitting device 120 is a device that emits light such as an LED. When each of the light emitting devices 120 has a square shape and the same size, in order to obtain an anisotropic illumination distribution required for a configuration of the linear lighting apparatus, the number of the light emitting devices 120 arranged in the direction of the long axis W1 should be larger than the number of the light emitting devices 120 arranged in the direction of the short axis W2 by at least 5/3 times or more. Meanwhile, the molding unit 130 may be a lens-integrated type package having the function of a lens while protecting the light emitting device 120, have an aspherical surface shape with its center recessed, and be formed of transparent resin such as silicon resin or epoxy resin.

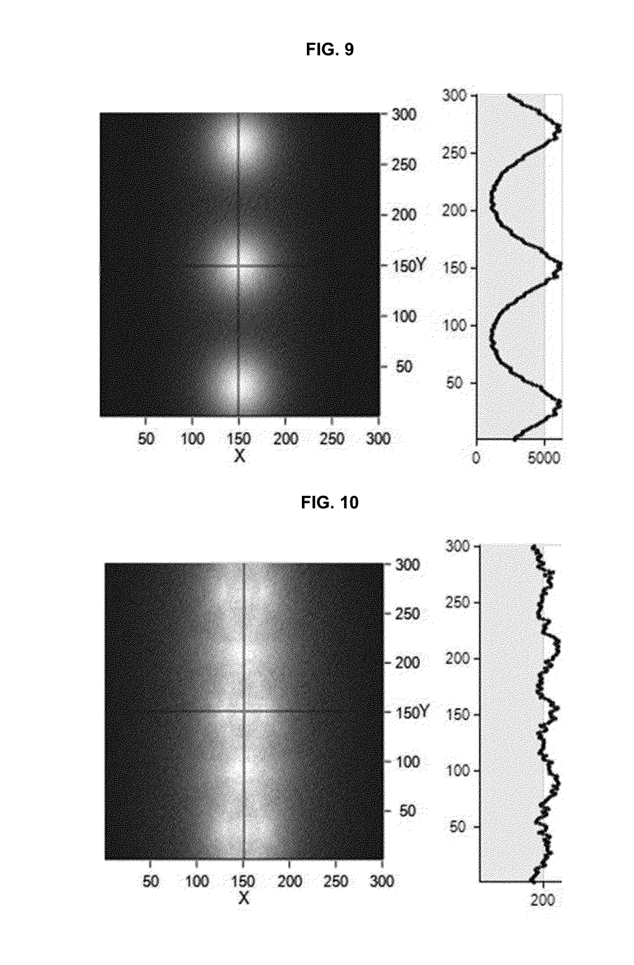

FIGS. 8 and 9 are views showing an illumination distribution of a linear lighting apparatus configured of a light emitting device package according to a comparative example, and FIG. 10 is a view showing an illumination distribution of a linear lighting apparatus configured of a light emitting device package according to an embodiment of the present disclosure. Here, the unit of the numerical values shown in FIGS. 8 to 10 is mm, and X and Y respectively indicate a first direction and a second direction intersecting the first direction.

Referring to FIG. 8, a linear lighting apparatus may be configured by arranging a plurality of light emitting device packages that are point light sources in a row. The light emitting device package including the square-shaped light emitting device according to a comparative example may have an isotropic illumination distribution, and therefore the number of the light emitting device packages required in a configuration of the linear lighting apparatus is relatively large.

Referring to FIG. 9, in a case in which the linear lighting apparatus is configured by arranging the light emitting device packages including the square-shaped light emitting device according to a comparative example in a row, when the number of the light emitting device packages in the linear lighting apparatus of FIG. 8 is reduced by half, each of the light emitting device packages is visually recognized as a point light source rather than as a linear light source.

Referring to FIG. 10, in a case in which the linear lighting apparatus is configured by arranging the plurality of light emitting device packages according to an embodiment of the present disclosure in a row, by arranging the light emitting device packages in the direction of the short axis in a row, in which the light emitted from the light emitting device package is widely diffused, each of the light emitting device packages may be visually recognized as the linear light source although the number of the light emitting device packages is reduced in the same manner as in a linear lighting module of FIG. 9.

As described above, according to the light emitting device package and the light apparatus including the same according to the embodiments of the present disclosure, the light emitting device may be formed into a rectangular shape or a plurality of light emitting devices may be arranged in a rectangular shape, and therefore an anisotropic illumination distribution may be obtained while applying an isotropic lens which can be easily designed and manufactured, thereby reducing manufacturing time and costs while increasing optical efficiency.

It will be apparent to those skilled in the art that various modifications can be made to the above-described exemplary embodiments of the present disclosure without departing from the spirit or scope of the disclosure. Thus, it is intended that the present disclosure covers all such modifications provided they come within the scope of the appended claims and their equivalents.

The present disclosure is directed to a light emitting device package which may obtain an anisotropic illumination distribution while applying an isotropic lens which can be easily designed and manufactured, and a light apparatus including the same.

According to an aspect of the present disclosure, there is provided a light emitting device package including: a light emitting device that has a first side extending in a first direction and a second side extending in a second direction, and is disposed on a substrate; and a molding unit that has a shape of an isotropic lens disposed on the substrate to surround the light emitting device, wherein a square root of {(length of the first side) 2+(length of the second side)2} is smaller than a diameter of the isotropic lens, and the length of the first side is at least 5/3 times more than the length of the second side.

Here, the isotropic lens may have an aspherical surface shape with its center recessed.

Also, a plurality of the light emitting devices may be arranged in the first direction and the second direction.

Also, the number of the light emitting devices arranged in the first direction may be at least 5/3 times more than the number of the light emitting devices arranged in the second direction.

Also, the first direction and the second direction may intersect each other.

According to another aspect of the present disclosure, there is provided a light emitting device package including: a substrate; a light emitting device that is disposed on the substrate and electrically connected to the substrate; and a molding unit that is disposed on the substrate to surround the light emitting device, wherein an upper surface of the light emitting device includes two first sides parallel to each other and two second sides parallel to each other that intersect the first sides, and the first sides are formed longer than the second sides.

Here, the first side and the second side may vertically intersect each other, and a length of the first side may be at least 5/3 times more than a length of the second side.

Also, the light emitting device may include a plurality of light emitting device units.

Also, the number of the light emitting device units arranged in a direction of the first side may be at least 5/3 times more than the number of the light emitting device units arranged in a direction of the second side.

Also, the molding unit may be an aspherical lens.

According to still another aspect of the present disclosure, there is provided a lighting apparatus including: at least one light emitting device package, wherein the light emitting device package includes a substrate, a light emitting device that is disposed on the substrate and electrically connected to the substrate, and a molding unit that is disposed on the substrate to surround the light emitting device, and wherein an upper surface of the light emitting device includes two first sides parallel to each other and two second sides parallel to each other that intersect the first sides, and the first sides are formed longer than the second sides.

Here, the first side and the second side may vertically intersect each other, and a length of the first side is at least 5/3 times more than a length of the second side.

Also, a plurality of the light emitting device packages may be provided, and arranged in a row.

Any reference in this specification to “one embodiment,” “an embodiment,” “example embodiment,” etc., means that a particular feature, structure, or characteristic described in connection with the embodiment is included in at least one embodiment of the disclosure. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A light emitting device package comprising:
a light emitting device that has a first side extending in a first direction and a second side extending in a second direction, and is disposed on a substrate; and
a molding unit that has a shape of an isotropic lens disposed on the substrate to surround the light emitting device,
wherein a square root of {(length of the first side)+(length of the second side)²} is smaller than a diameter of the isotropic lens, and the length of the first side is at least 5/3 times more than the length of the second side.

2. The light emitting device package of claim 1, wherein the isotropic lens has an aspherical surface shape with its center recessed.

3. The light emitting device package of claim 1, wherein a plurality of the light emitting devices are arranged in the first direction and the second direction.

4. The light emitting device package of claim 3, wherein the number of the light emitting devices arranged in the first direction is at least 5/3 times more than the number of the light emitting devices arranged in the second direction.

5. The light emitting device package of claim 1, wherein the first direction and the second direction intersect each other.

6. A light emitting device package comprising:
a substrate;
a light emitting device that is disposed on the substrate and electrically connected to the substrate; and
a molding unit that is disposed on the substrate to surround the light emitting device,
wherein an upper surface of the light emitting device includes two first sides parallel to each other and two second sides parallel to each other that intersect the first sides, and the first sides are formed longer than the second sides.

7. The light emitting device package of claim 6, wherein the first side and the second side vertically intersect each other, and a length of the first side is at least 5/3 times more than a length of the second side.

8. The light emitting device package of claim 6, wherein the light emitting device includes a plurality of light emitting device units.

9. The light emitting device package of claim 8, wherein the number of the light emitting device units arranged in a direction of the first side is at least 5/3 times more than the number of the light emitting device units arranged in a direction of the second side.

10. The light emitting device package of claim 6, wherein the molding unit is an aspherical lens.

11. A lighting apparatus comprising:
at least one light emitting device package,
wherein the light emitting device package includes
a substrate,
a light emitting device that is disposed on the substrate and electrically connected to the substrate, and
a molding unit that is disposed on the substrate to surround the light emitting device, and
wherein an upper surface of the light emitting device includes two first sides parallel to each other and two second sides parallel to each other that intersect the first sides, and the first sides are formed longer than the second sides.

12. The lighting apparatus of claim 11, wherein the first side and the second side vertically intersect each other, and a length of the first side is at least 5/3 times more than a length of the second side.

13. The lighting apparatus of claim 11, wherein a plurality of the light emitting device packages are provided, and arranged in a row.
